(19) United States
(12) Patent Application Publication
(10) Pub. No.: US 2026/0238894 A1
(43) Pub. Date: Aug. 13, 2026

(54) IMAGE SENSOR AND IMAGE PROCESSING DEVICE INCLUDING THE SAME

(71) Applicant: SAMSUNG ELECTRONICS CO., LTD., Suwon-si (KR)

(72) Inventor: Hyounjee HA, Suwon-si (KR)

(73) Assignee: SAMSUNG ELECTRONICS CO., LTD., Suwon-si (KR)

(21) Appl. No.: 19/531,966

(22) Filed: Feb. 6, 2026

(30) Foreign Application Priority Data
Feb. 7, 2025 (KR) 10-2025-0016167

(51) Int. Cl. H04N 25/47; H04N 25/10; H04N 25/78

(52) U.S. Cl. CPC H04N 25/47; H04N 25/10; H04N 25/78

(57) ABSTRACT

Provided are an image sensor and an image processing device including the same. The image sensor includes a pixel array including a plurality of pixel groups, wherein at least one pixel group from among the plurality of pixel groups includes a first pixel configured to generate image data and a second pixel configured to generate event data, and the first pixel and the second pixel included in the same pixel group are configured to receive an optical signal of a same color, and a dynamic vision sensor (DVS) circuit configured to generate an event signal, based on an electrical signal corresponding to charge generated from the second pixel.

### CROSS-REFERENCE TO RELATED APPLICATION

This application is based on and claims priority under 35 U.S.C. §119 to Korean Patent Application No. 10-2025-0016167, filed on February 7, 2025, in the Korean Intellectual Property Office, the disclosure of which is incorporated herein in its entirety by reference.

### BACKGROUND

The disclosure relates to a semiconductor device, and more particularly, to an image sensor and an image processing device including the same.

Human-computer interaction (HCI) is expressed and operates in a user interface. Various user interfaces that recognize user inputs may provide natural interaction between a human and a computer. Various sensors may be used to recognize user inputs.

An image sensor device is a device that generates electrical signals or digital signals on the basis of light incident from outside. Recently, event-based sensors that output event signals according to the amount of change in the intensity of light from outside, such as dynamic vision sensors (DVSs), are being developed. An event-based sensor uses various components such as a converter and an amplifier to output event signals.

### SUMMARY

One or more example embodiments of the disclosure provide (an image sensor including a first pixel, a complementary metal oxide semiconductor (CMOS) image sensor (CIS) pixel, and a second pixel, a dynamic vision sensor (DVS) pixel, wherein the first pixel and the second pixel are pixels of the same color, and an image processing device including the same.

According to an aspect of an example embodiment of the disclosure, there is provided an image sensor including: a pixel array including a plurality of pixel groups, wherein at least one pixel group from among the plurality of pixel groups includes a first pixel configured to generate image data and a second pixel configured to generate event data, and the first pixel and the second pixel included in a same pixel group are configured to receive an optical signal of a same color, and a DVS circuit configured to generate an event signal based on an electrical signal corresponding to a charge generated from the second pixel.

According to an aspect of an example embodiment of the disclosure, there is provided an image sensor including: a pixel array including a plurality of pixel groups, wherein at least one pixel group from among the plurality of pixel groups includes a first pixel and a second pixel; a dynamic vision sensor (DVS) circuit configured to generate an event signal, based on a first electrical signal corresponding to a charge generated from the second pixel; a pixel circuit configured to generate a pixel signal, based on a second electrical signal corresponding to a charge generated from the first pixel; a read-out circuit configured to generate image data, based on the pixel signal; and an event detection circuit configured to generate event data based on the event signal, wherein, from among the plurality of pixel groups, a first pixel group includes N first pixels and M second pixels (N and M are natural numbers), and wherein the N first pixels and the M second pixels are configured to receive optical signals of a first color and convert the optical signals into electrical signals.

According to an aspect of an example embodiment of the disclosure, there is provided an image processing device including: a pixel array including a plurality of pixel groups, wherein at least one pixel group from among the plurality of pixel groups includes a first pixel and a second pixel; a signal processing circuit configured to process a signal received from the pixel array and output data; and a processor configured to detect a movement of an object based on the output data, wherein the first pixel and the second pixel included in a first pixel group from among the at least one pixel group are configured to receive an optical signal of a first color, and wherein the first color is one of red, green, and blue.

### BRIEF DESCRIPTION OF THE DRAWINGS

Embodiments of the disclosure will be more clearly understood from the following detailed description taken in conjunction with the accompanying diagrams in which:

FIG. 1 is a block diagram showing an image processing device according to an embodiment;

FIG. 2 is a block diagram showing an image sensor according to an embodiment;

FIG. 3 is a block diagram of pixel groups including first pixels and second pixels, according to an embodiment;

FIG. 4 is a plan view of pixel groups including first pixels and second pixels, according to an embodiment;

FIG. 5 is a circuit diagram of pixel groups including first pixels and second pixels, according to an embodiment;

FIG. 6 is a cross-sectional view taken along a line A-A’ of FIG. 4, according to an embodiment;

FIG. 7 is a block diagram of pixel groups including first pixels and second pixels, according to an embodiment;

FIG. 8 is a block diagram of pixel groups including first pixels and second pixels, according to an embodiment;

FIG. 9 is a block diagram of pixel groups including first pixels and second pixels, according to an embodiment;

FIG. 10 is a block diagram of pixel groups including first pixels and second pixels, according to an embodiment;

FIG. 11 is a plan view of pixel groups including first pixels and second pixels, according to an embodiment;

FIG. 12 is a circuit diagram showing a dynamic vision sensor (DVS) circuit according to an embodiment;

FIG. 13 is a diagram showing a three-stack structure of an image processing device, according to an embodiment;

FIG. 14 is a block diagram of a pixel array including first pixels and second pixels, according to an embodiment; and

FIG. 15 is a block diagram showing an electronic device to which an image sensor according to an embodiment is applied.

### DETAILED DESCRIPTION

Hereinafter, example embodiments of the present disclosure will be described with reference to the accompanying drawings.

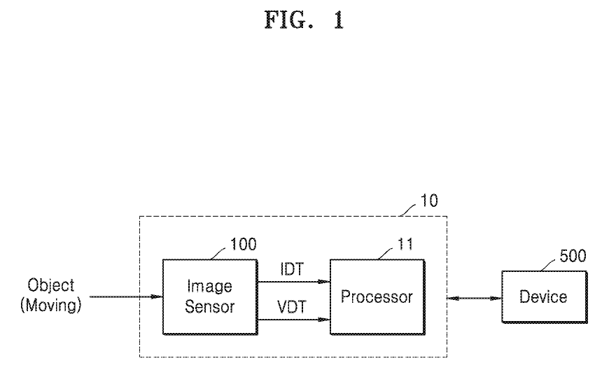

FIG. 1 is a block diagram showing an image processing device 10 according to an embodiment.

Referring to FIG. 1, the image processing device 10 may include an image sensor 100 and a processor 11. The image processing device 10 according to an embodiment may be mounted on an electronic device having a function of sensing an image or light.

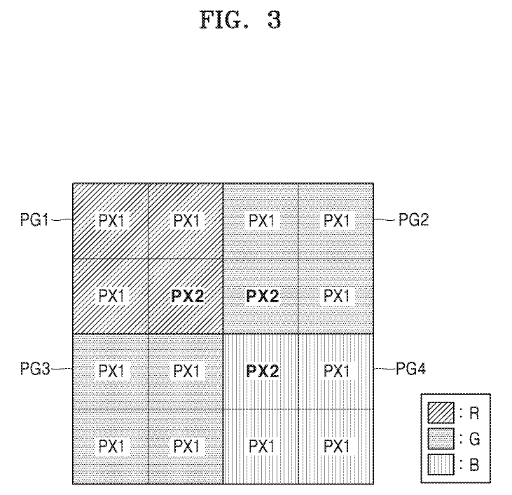

The image sensor 100 may include a first pixel (e.g., PX1 of FIG. 3) and a second pixel (e.g., PX2 of FIG. 3). According to an embodiment, the image sensor 100 may include a plurality of first pixels PX1 and a plurality of second pixels PX2. The number of the plurality of first pixels PX1 may be greater than the number of the plurality of second pixels PX2. The image sensor 100 may include a first pixel PX1 for generating image data IDT corresponding to an image of an object and a second pixel PX2 for detecting movement of the object. According to an embodiment, the first pixel PX1 may be a complementary metal oxide semiconductor (CMOS) image sensor (CIS) pixel, and the second pixel PX2 may be a dynamic vision sensor (DVS) pixel. For example, the first pixel PX1 may be one of an RGB pixel (e.g., one of a red pixel, a green pixel, and a blue pixel), a BW pixel (e.g., one of a black pixel and a white pixel), or an ultraviolet (UV) pixel, and the second pixel PX2 may also be one of an RGB pixel, a BW pixel, or an UV pixel similarly to the first pixel PX1.

As described above, the image sensor 100 may be a hybrid sensor including both the first pixel PX1 for generating the image data IDT of an object and the second pixel PX2 for detecting movement of the object. The image sensor 100 may generate and output both the image data IDT and vision sensor data (or event data) VDT. Also, the image sensor 100 may output only the image data IDT or only the vision sensor data VDT according to a mode. For example, the image sensor 100 may generate the image data IDT using signals generated from the plurality of first pixels PX1 in an image-frame capture mode and may generate the vision sensor data VDT using signals generated from the plurality of second pixels PX2 in an event-based vision sensor (EVS) mode.

For example, the first pixel PX1 may be a color pixel. The first pixel PX1 may be a red pixel that converts light in a red spectrum region into an electrical signal. The first pixel PX1 may be a green pixel that converts light in a green spectrum region into an electrical signal. The first pixel PX1 may be a blue pixel that converts light in a blue spectrum region into an electrical signal. The first pixel PX1 may be a cyan pixel that converts light in a blue spectrum region to a green spectrum region into an electrical signal. The first pixel PX1 may be a yellow pixel that converts light in a green spectrum region to a red spectrum region into an electrical signal. The first pixel PX1 may be a magenta pixel that converts light in a blue spectrum region to a red spectrum region into an electrical signal.

According to an embodiment, the second pixel PX2 may be the same color pixel as the first pixel PX1. For example, the first pixel PX1 and the second pixel PX2 included in a same pixel group may be color pixels of a same color. The second pixel PX2 may be a red pixel that converts light in a red spectrum region into an electrical signal. The second pixel PX2 may be a green pixel that converts light in a green spectrum region into an electrical signal. The second pixel PX2 may be a blue pixel that converts light in a blue spectrum region into an electrical signal. The second pixel PX2 may be a cyan pixel that converts light in a blue spectrum region to a green spectrum region into an electrical signal. The second pixel PX2 may be a yellow pixel that converts light in a green spectrum region to a red spectrum region into an electrical signal. The second pixel PX2 may be a magenta pixel that converts light in a blue spectrum region to a red spectrum region into an electrical signal.

According to a comparative example, in the image sensor, a color of the second pixel PX2 included in a pixel group may be different from a color of the first pixel PX1 included in the same pixel group (that is, included in that pixel group). For example, in the image sensor according to the comparative example, the first pixel PX1 included in a pixel group may formed as at least one of a red pixel, a green pixel, and a blue pixel and the second pixel PX2 included in the same pixel group may formed as a white pixel. Since the second pixel PX2 is a white color pixel having a different color from the first pixel PX1, crosstalk may occur due to interference between the first pixel PX1 and second pixel PX2 adjacent to each other.

However, according to an embodiment, the image sensor 100 may include the first pixel PX1 that is a color pixel and the second pixel PX2 that is the same color pixel as the first pixel PX1. Since the second pixel PX2 includes the same color pixel as the first pixel PX1, the interference therebetween may be eliminated, and thus the image sensor 100 may exhibit reduced crosstalk.

The image sensor 100 may convert an optical signal of an object into an electrical signal, generate the image data IDT, based on electrical signals, and transmit the image data IDT to the processor 11. The first pixel PX1 and the second pixel PX2 may each charge (e.g., a photocharge) according to an amount of light incident thereto (e.g., an optical signal). For example, the first pixel PX1 and the second pixel PX2 may each convert light incident thereto into photocharges and accumulate the photocharges. The image sensor 100 may generate the image data IDT, based on electrical signals (e.g., first electrical signals) corresponding to charges generated from the plurality of first pixels PX1. The image sensor 100 may detect a change in an intensity of incident light based on electrical signals (e.g., second electrical signals) corresponding to charges generated from the plurality of second pixels PX2 and output an event signal based on the detected change. The change in light intensity may be due to movement of an object captured by the image sensor 100 or due to movement of the image sensor 100 or movement of the image processing device 10 itself. The image sensor 100 may generate an event signal periodically or aperiodically and transmit the vision sensor data VDT including the event signal to the processor 11 periodically or aperiodically. The vision sensor data VDT may be generated by using only an event signal generated from one frame or may be generated by grouping event signals generated from multiple frames.

The image sensor 100 may capture an image of an object and generate the image data IDT, based on received control signals. The image data IDT may include a still image and/or a moving image. The image sensor 100 may perform signal processing such as image quality compensation, binning, and downsizing on the image data IDT and the vision sensor data VDT, and the image quality compensation may include, for example, signal processing such as black level compensation, lens shading compensation, crosstalk compensation, and bad pixel correction.

The processor 11 may process the image data IDT and the vision sensor data VDT received from the image sensor 100. The processor 11 may detect movement of an object (or movement of an object on an image recognized by the image processing device 10) based on an event signal in the vision sensor data VDT. For example, but not limited thereto, the processor 11 may be an application processor or an image signal processor.

For example, but not limited thereto, the processor 11 may include an application specific integrated circuit (ASIC), a field-programmable gate array (FPGA), a dedicated microprocessor, a microprocessor, a general purpose processor, etc. According to an embodiment, the processor 11 may be an application processor or an image signal processor, for example but not limited thereto.

Alternatively, the image sensor 100 and the processor 11 may each be implemented as an integrated circuit (IC) or may be implemented as a single chip by being implemented as a semiconductor substrate. For example, the image sensor 100 and the processor 11 may be implemented as separate semiconductor chips, or the image sensor 100 and the processor 11 implemented as separate semiconductor chips may be placed in one package PKG. In another example, the image sensor 100 and the processor 11 implemented as separate semiconductor substrates may be implemented as a single chip through a through-silicon via TXV or a copper-to-copper connection.

When the image sensor 100 includes only the second pixels PX2 without the first pixels PX1, the image sensor 100 is unable to generate an event signal when there is no movement of an object, and thus the image sensor 100 is unable to provide any data to the processor 11.

However, since the image sensor 100 according to an embodiment includes the first pixel PX1 (e.g., a CIS pixel) and the second pixel PX2 (e.g., a dynamic vision sensor (DVS) pixel), even when there is no movement of an object, the image data IDT based on an electrical signal corresponding to the amount of light incident on the first pixel PX1 may be provided to the processor 11. Therefore, data may be provided regardless of the movement of an object. Also, the image sensor 100 may detect a change in the amount of light incident on the second pixel PX2 and provide the vision sensor data VDT based on an electrical signal corresponding to a detected change to the processor 11.

The image processing device 10 may control a device 500, provided externally, to collect data. The image processing device 10 may match the image data IDT and/or the vision sensor data VDT to the data collected from the device 500. The device 500 may include, for example but not limited to, an acceleration sensor, an inertial measurement unit (IMU), a gyro sensor, an infrared (IR) light emitting diode (LED), and a flash light.

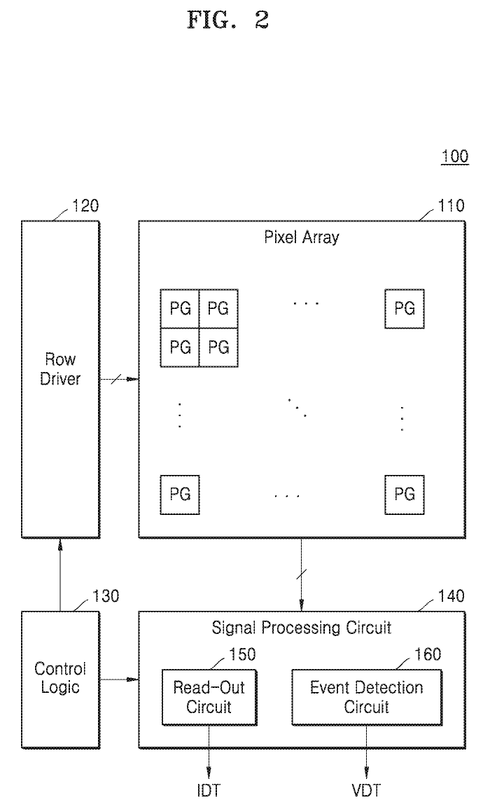

FIG. 2 is a block diagram showing an image sensor 100 according to an embodiment.

Referring to FIGS. 1 and 2, the image sensor 100 may include a pixel array 110, a row driver 120, a control logic circuit 130, and a signal processing circuit 140. The signal processing circuit 140 may include a read-out circuit 150 and an event detection circuit 160.

The pixel array 110 may include a plurality of pixel groups PG arranged in rows and columns. The plurality of pixel groups PG may each include a plurality of pixels arranged in rows and columns, and the plurality of pixels may each include a photodiode and a transfer transistor. A pixel group PG may include N first pixels PX1 and M second pixels PX2. Here, M and N are natural numbers, and N may be greater than M.

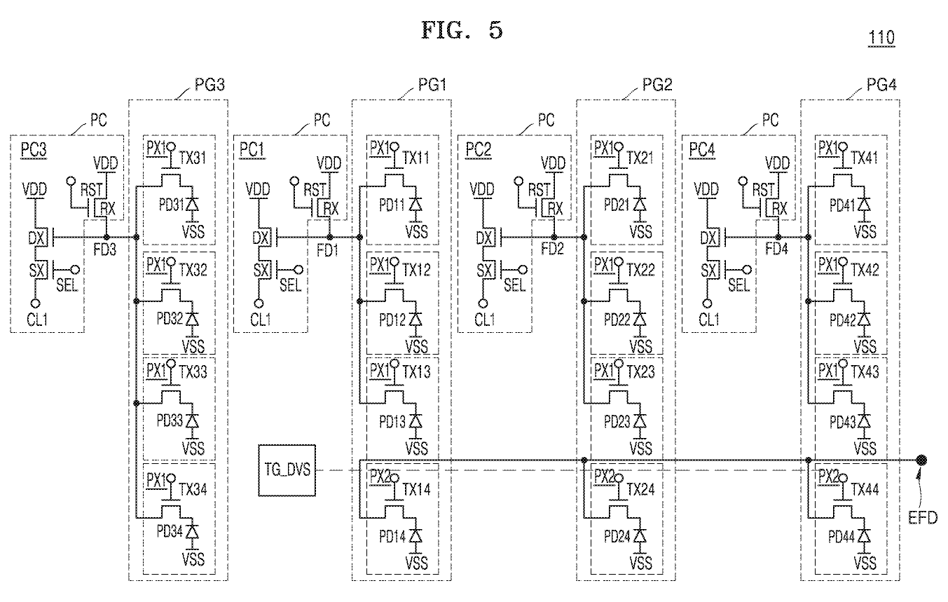

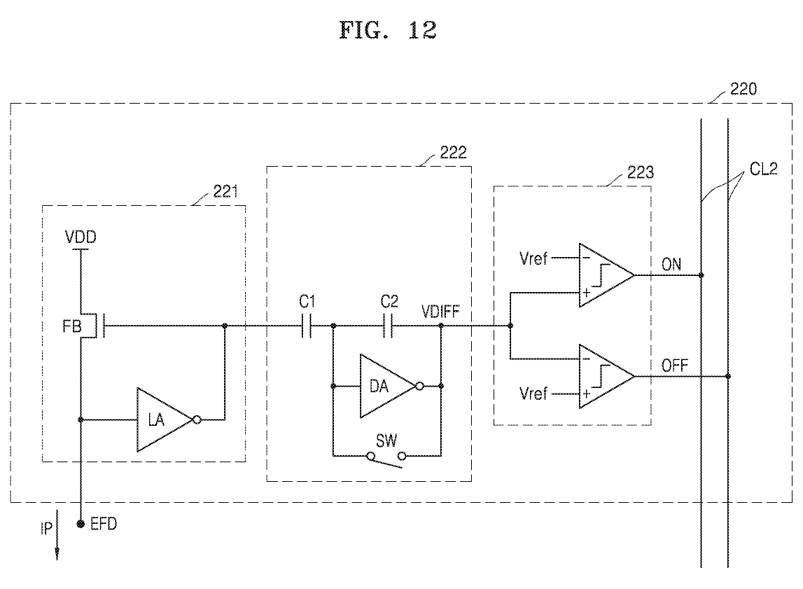

The pixel array 110 may further include a pixel circuit (e.g., PC of FIG. 5) each configured to generate a pixel signal (or a pixel voltage, or an image signal), based on charges (e.g., photocharges) generated from the first pixels PX1 (e.g., N first pixels PX1) included in one pixel group PG and a DVS circuit (e.g., 220 of FIG. 12) configured to detect a change in the amount of incident light, based on charges generated from the second pixels PX2 and generate an event signal (e.g., an on-event signal and/or an off-event signal). The pixel array 110 may include a plurality of pixel circuits PC and a plurality of DVS circuits 220.

The pixel array 110 may further include a plurality of row lines extending in a row-wise direction (e.g., a X-axis direction) and a plurality of column lines extending in a column-wise direction (e.g., a Y-axis direction). According to an embodiment, the plurality of column lines may include a plurality of first column lines (e.g., CL1 of FIG. 5) connected to the plurality of pixel circuits PC and a plurality of second column lines (e.g., CL2 of FIG. 12) connected to the plurality of DVS circuits 220.

According to an embodiment, the plurality of pixel circuits and/or the plurality of DVS circuits may be formed separately from the plurality of pixel groups PG. For example, the pixel array 110 may include a first pixel array and a second pixel array, the first pixel array may include the plurality of pixel groups PG, and not the plurality of pixel circuits and/or the plurality of DVS circuits, and the second pixel array may include the plurality of pixel circuits and/or the plurality of DVS circuits, and not the plurality of pixel groups PG. The first pixel array and the second pixel array may be formed on different semiconductor layers.

The pixel array 110 may further include a plurality of row lines extending in a row-wise direction (e.g., the X-axis direction) and a plurality of column lines extending in a column-wise direction (e.g., the Y-axis direction). According to an embodiment, the plurality of column lines may include a plurality of first column lines (e.g., CL1 of FIG. 5) connected to the plurality of pixel circuits PC and a plurality of second column lines (e.g., CL2 of FIG. 12) connected to the plurality of DVS circuits 220.

The row driver 120 may activate the first pixels PX1 row-by-row under control of the control logic circuit 130. The row driver 120 may provide control signals (e.g., a transmission control signal, a reset signal, a selection signal, etc.) to the first pixels PX1, the second pixels PX2, and the pixel circuits PC through the row lines.

The control logic circuit 130 may control the overall operation of the image sensor 100 based on a control signal provided from the processor 11. The control logic circuit 130 may control each of the row driver 120 and the signal processing circuit 140.

The signal processing circuit 140 may generate the image data IDT and the vision sensor data (or event data) VDT based on first electrical signals corresponding to charges output from the first pixels PX1 of the pixel array 110 and second electrical signals corresponding to charges output from the second pixels PX2 of the pixel array 110. The vision sensor data VDT may include event data generated based on the second pixel signals.

The signal processing circuit 140 may include the read-out circuit 150 and the event detection circuit 160. The read-out circuit 150 may receive pixel signals from the pixel array 110 and generate the image data IDT based on received pixel signals. The read-out circuit 150 may receive pixel signals from the pixel array 110 through a plurality of first column lines CL1. The read-out circuit 150 may perform analog-to-digital conversion of the pixel signals to generate the image data IDT.

According to an embodiment, the read-out circuit 150 may include a ramp signal generator, a plurality of analog-to-digital converter (ADC) circuits, and an output buffer (not shown), and the plurality of ADC circuits may each include a comparator and a counter.

The event detection circuit 160 may receive an event signal from the pixel array 110 and process the event signal to generate the vision sensor data VDT. The event detection circuit 160 may receive the event signal from the pixel array 110 through a plurality of second column lines CL2. The event detection circuit 160 may include a column address event representation (AER) circuit (not shown), a row AER circuit (not shown), and an output buffer (not shown).

The image sensor 100 may detect an event in which the intensity of light changes, determine a type of the event (e.g., whether the detected event is an event in which the intensity of light increases or decreases), and output a value corresponding to the event. For example, an event may occur primarily at an outline of a moving object.

A DVS circuit (e.g., 220 of FIG. 12) connected to at least one second pixel PX2 that detected an event from among a plurality of pixels may generate a signal (e.g., a column request) notifying that an event in which the intensity of light increases or decreases has occurred based on an electrical signal provided from the at least one second pixel PX2 and transmit the signal (e.g., column request) to the column AER circuit.

The column AER circuit may transmit a response signal to the DVS circuit 220 in response to a received column request. The DVS circuit 220 that receives the response signal may transmit polarity information of an occurred event to the row AER circuit. The column AER circuit may generate a column address of the at least one second pixel PX2 that detected the event based on the column request received from the DVS circuit 220 connected to the at least one second pixel PX2.

The row AER circuit may receive polarity information from the DVS circuit 220 connected to the at least one second pixel PX2 that detected the event. The row AER circuit may generate a time stamp including information regarding a time at which the event occurred, based on the polarity information. For example, the time stamp may be generated by a time stamper (not shown) provided in the row AER circuit. For example, the time stamper may be implemented by using timeticks that are generated in units of several to dozens of microseconds. Also, the row AER circuit may generate a row address of the at least one second pixel PX2 that detected the event.

The output buffer may generate packets based on a time stamp, a column address, a row address, and polarity information. The output buffer may add a header indicating a beginning of the packet to a front end of the packet and a tail indicating an end of the packet to a rear end of the packet. For example, at least some of the column AER, the row AER, and the output buffer described above may be referred to as DVS peripheral circuits.

According to an embodiment, the image sensor 100 may include the first pixel PX1 that is a color pixel and the second pixel PX2 that is the same color pixel as the first pixel PX1. Since the second pixel PX2 is implemented as a pixel of the same color as the first pixel PX1, interference between pixels that occurs when the colors of the first pixel PX1 and the second pixel PX2 adjacent to each other are different during operation of the image sensor 100 may be suppressed and crosstalk may be reduced.

FIG. 3 is a block diagram of a plurality of pixel groups PG1 to PG4 including the first pixels PX1 and the second pixels PX2, according to an embodiment.

Referring to FIGS. 2 and 3, the pixel array 110 may include the plurality of pixel groups PG1 to PG4 arranged in rows and columns. For example, the pixel array 110 may include 16 pixels arranged in a 4×4 matrix (i.e., 4 rows and 4 columns). Here, a pixel may include a photodiode and a transfer transistor.

A pixel may further include a color filter and/or a micro-lens. The pixel array 110 may include four first to fourth pixel groups PG1 to PG4 arranged in a 2×2 matrix (i.e., 2 rows and 2 columns).

At least one pixel group from among the first to fourth pixel groups PG1 to PG4 may include the plurality of first pixels PX1 and the second pixel PX2. For example, a first pixel group PG1, a second pixel group PG2, and a fourth pixel group PG4 may each include the plurality of first pixels PX1 and at least one second pixel PX2. For example, in each of the first pixel group PG1, the second pixel group PG2, and the fourth pixel group PG4, the number of the first pixels PX1 may be greater than the number of the second pixels PX2. A third pixel group PG3 may include the plurality of first pixels PX1 excluding the second pixel PX2.

According to an embodiment, the first pixel group PG1, the second pixel group PG2, and the fourth pixel group PG4 may each include N first pixels PX1 and M second pixels PX2. For example, N may be ‘3’ and M may be ‘1’. The third pixel group PG3 may include four first pixels PX1.

Positions of the second pixels PX2 included in the first pixel group PG1, the second pixel group PG2, and the fourth pixel group PG4 excluding the third pixel group PG3 may be different within each pixel group.

For example, as shown in FIG. 3, the second pixel PX2 included in the first pixel group PG1 may be arranged at a lower right corner within a region in which the first pixel group PG1 is formed, the second pixel PX2 included in the second pixel group PG2 may be arranged at a lower left corner within a region in which the second pixel group PG2 is formed, and the second pixel PX2 included in the fourth pixel group PG4 may be arranged at an upper left corner within a region in which the fourth pixel group PG4 is formed. For example, the second pixel PX2 may be placed in a second row and a second column of the first to fourth pixel groups PG1 to PG4 (or in a second row and a second column of the first pixel group PG1), the second pixel PX2 may be placed in a second row and a third column of the first to fourth pixel groups PG1 to PG4 (or in a second row and a first column of the second pixel group PG2), and the second pixel PX2 may be placed in a third row and a third column of the first to fourth pixel groups PG1 to PG4 (or in a first row and a first column of the fourth pixel group PG4). The second pixels PX2 may be positioned at edge regions where the first to fourth pixel groups PG1 to PG4 meet one another. The second pixels PX2 may each be positioned in a center portion of a pixel block including the first to fourth pixel groups PG1 to PG4. For example, the second pixels PX2 may be placed adjacent to one another.

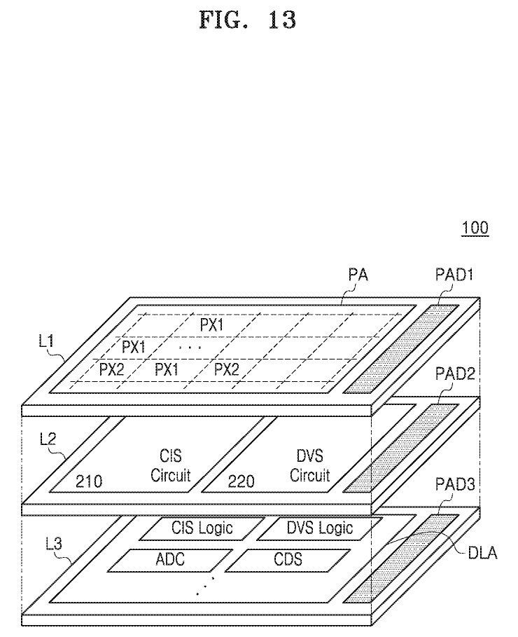

The image sensor 100 may be implemented as a semiconductor chip or a semiconductor module including a plurality of vertically stacked semiconductor layers, and, at this time, photodiodes and transfer transistors included in the first pixel group PG1 may be formed in a first layer (e.g., L1 of FIG. 13), photodiodes and transfer transistors included in the second pixel group PG2 may be formed in the first layer L1, photodiodes and transfer transistors included in the third pixel group PG3 may be formed in the first layer L1, and photodiodes and transfer transistors included in the fourth pixel group PG4 may be formed in the first layer L1. Reset transistors, driving transistors, and selection transistors provided in pixel circuits (e.g., PC1, PC2, PC3, and PC4 of FIG. 5) electrically and respectively connected to the first to fourth pixel groups PG1 to PG4 may be formed in the first layer L1. However, embodiments are not limited thereto, and pixel circuits may be formed in the second layer L2. Detailed descriptions thereof will be given later with reference to FIG. 13.

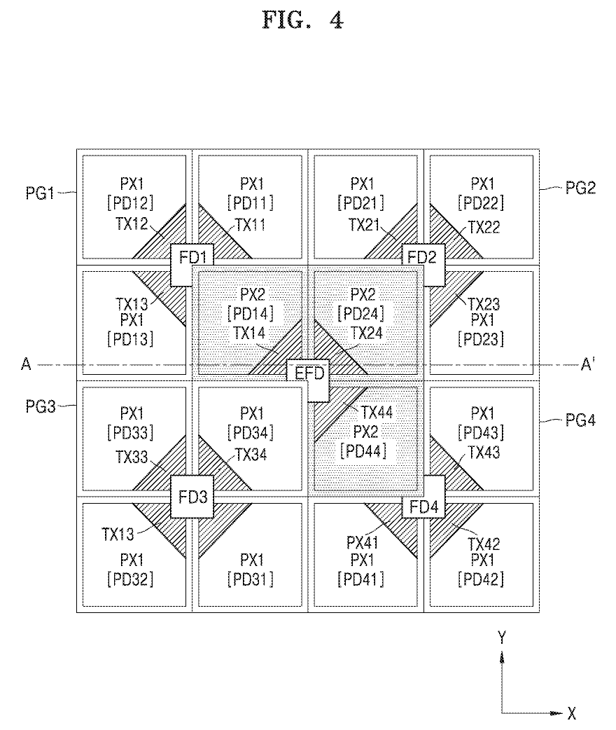

In each of the first pixel group PG1, the second pixel group PG2, the third pixel group PG3, and the fourth pixel group PG4, the first pixels PX1 may share a floating diffusion node (also referred to as a floating diffusion region). The second pixels PX2 included in the first pixel group PG1, the second pixel group PG2, and the third pixel group PG3 may share an event floating diffusion node and a DVS circuit (e.g., 220 of FIG. 12). For example, the second pixels PX2 included in the first pixel group PG1, the second pixel group PG2, and the third pixel group PG3 may share a current/voltage converter, an amplifier circuit, and a comparator circuit. The DVS circuit 220 may be formed in the second layer L2. Detailed descriptions thereof will be given later with reference to FIGS. 4, 5, and 13.

The first to fourth pixel groups PG1 to PG4 may be of the same type or different types. The first to fourth pixel groups PG1 to PG4 may have a Bayer pattern, e.g., an RGBG pattern. However, the disclosure is not limited thereto.

According to an embodiment, the first pixels PX1 may include any one of a red pixel, a green pixel, a blue pixel, a cyan pixel, a yellow pixel, or a magenta pixel. The second pixels PX2 may include any one of a red pixel, a green pixel, a blue pixel, a cyan pixel, a yellow pixel, or a magenta pixel.

According to an embodiment, the plurality of first pixels PX1 and the second pixel PX2 included in the same pixel group may be implemented as the same color pixels. The plurality of first pixels PX1 and the second pixels PX2 may detect an optical signal of the same color (e.g., an optical signal of the same wavelength band) and may convert the detected optical signal into charges. For example, the first pixel group PG1 may include three first pixels PX1 corresponding to a red pixel R and one second pixel PX2 corresponding to the red pixel R. For example, the second pixel group PG2 may include three first pixels PX1 corresponding to a green pixel G and one second pixel PX2 corresponding to the green pixel G. For example, the third pixel group PG3 may include four first pixels PX1 corresponding to a blue pixel B. For example, the fourth pixel group PG4 may include three first pixels PX1 corresponding to the green pixel G and one second pixel PX2 corresponding to the green pixel G. However, the disclosure is not limited thereto.

FIG. 4 is a plan view of the pixel groups PG1 to PG4 including the first pixels PX1 and the second pixels PX2, according to an embodiment. FIG. 5 is a circuit diagram of the pixel groups PG1 to PG4 including the first pixels PX1 and the second pixels PX2, according to an embodiment.

Referring to FIGS. 4 and 5 together, the first pixel group PG1, the second pixel group PG2, and the fourth pixel group PG4 may each include three first pixels PX1 and one second pixel PX2. The first pixel PX1 and the second pixel PX2 may each include a photodiode and a transfer transistor connected thereto. Therefore, the first pixel group PG1 may include four photodiodes PD11 to PD14 and four transfer transistors TX11 to TX14 respectively connected thereto, the second pixel group PG2 may include four photodiodes PD21 to PD24 and four transfer transistors TX21 to TX24 respectively connected thereto, the third pixel group PG3 may include four photodiodes PD31 to PD34 and four transfer transistors TX31 to TX34 respectively connected thereto, and the fourth pixel group PG4 may include four photodiodes PD41 to PD44 and four transfer transistors TX41 to TX44 respectively connected thereto.

Micro-lenses may be stacked on top of each of first to fourth pixel groups PG1, PG2, PG3, and PG4. For example, a micro-lens may be placed on one first photodiode PD11, and the first photodiode PD11 may receive an optical signal through the micro-lens placed thereon. A micro-lens may be placed on each pixel. Also, additionally or alternatively to micro-lenses, nano prisms, meta lenses, etc. may be placed on each pixel.

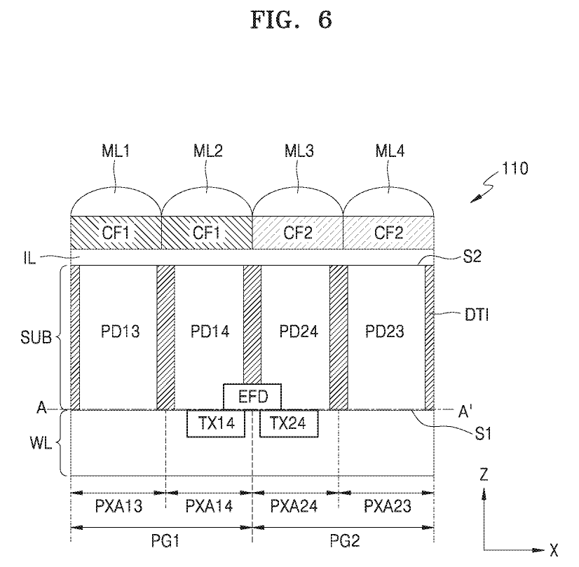

Color filters may be arranged between the photodiodes PD11 to PD14, PD21 to PD24, PD31 to PD34, and PD41 to PD44 and micro-lenses, and the color filters provided in the first to fourth pixel groups PG1 to PG4 may transmit optical signals of the same and/or different colors. Detailed descriptions thereof will be given later with reference to FIG. 6.

Referring to FIG. 4, the first pixels PX1 included in the first pixel group PG1 may share a first floating diffusion node FD1. The first pixels PX1 included in the second pixel group PG2 may share a second floating diffusion node FD2. The first pixels PX1 included in the third pixel group PG3 may share a third floating diffusion node FD3. The first pixels PX1 included in the fourth pixel group PG4 may share a fourth floating diffusion node FD4. Photocharges generated from each of the photodiodes PD11 to PD13, PD21 to PD23, PD31 to PD34, and PD41 to PD43 provided in the first pixel PX1 may be transferred and accumulated in shared floating diffusion nodes FD1, FD2, FD3, and FD4. For example, photocharges generated from each of the first to third photodiodes PD11 to PD13 of the first pixel group PG1 may be transmitted to the first floating diffusion node FD1, photocharges generated from each of the first to third photodiodes PD21 to PD23 of the second pixel group PG2 may be transmitted to the second floating diffusion node FD2, photocharges generated from each of the first to fourth photodiodes PD31 to PD34 of the third pixel group PG3 may be transmitted to the third floating diffusion node FD3, and photocharges generated from each of the first to third photodiodes PD41 to PD43 of the fourth pixel group PG4 may be transmitted to the fourth floating diffusion node FD4.

The concept of sharing between the pixel groups PG1 to PG4 may include not only the meaning that each group of the plurality of photodiodes PD11 to PD13, PD21 to PD23, PD31 to PD34, and PD41 to PD43 shares a single floating diffusion node FD1, FD2, FD3, or FD4, but also the meaning that transistors other than the transfer transistors TX11 to TX13, TX21 to TX23, TX31 to TX34, and TX41 to TX43, such as a reset transistor, a driving transistor, and a selection transistor included in a pixel circuit (e.g., the PC of FIG. 5) are shared. Photocharges generated from the photodiodes PD11 to PD13, PD21 to PD23, PD31 to PD34, and PD41 to PD43 provided in the first pixels PX1 are transmitted and accumulated to the shared floating diffusion nodes FD1, FD2, FD3, and FD4, respectively, and the pixel circuit PC may output pixel signals corresponding to photocharges accumulated in the respective shared floating diffusion nodes FD1, FD2, FD3, and FD4 to a read-out circuit (150 of FIG. 2).

The second pixel PX2 included in the first pixel group PG1, the second pixel PX2 included in the second pixel group PG2, and the second pixel PX2 included in the fourth pixel group PG4 may share an event floating diffusion node EFD.

The concept of sharing between the pixel groups PG1 to PG4 may include not only the meaning that photodiodes PD14, PD24, and PD44 share one event floating diffusion node, but also the meaning that the photodiodes PD14, PD24, and PD44 share the DVS circuit (220 of FIG. 12). Photocharges generated from respective photodiodes are transferred and accumulated in the shared event floating diffusion node EFD, and the DVS circuit 220 may generate an event signal based on photocharges accumulated in the event floating diffusion node EFD.

In each pixel group, the plurality of first pixels PX1 or the plurality of first pixels PX1 and the plurality of second pixels PX2 may be arranged in rows and columns. A floating diffusion node may be placed in a center portion of each pixel group, and the event floating diffusion node EFD may be placed at an edge region of each pixel group, and edge regions of the pixel groups PG1 to PG4 where the event floating diffusion node EFD is placed may be adjacent to each other.

For example, a substrate on which the plurality of photodiodes PD11 to PD14, PD21 to PD24, PD31 to PD34, and PD41 to PD44 are formed may include a plurality of regions, and a plurality of photodiodes included in corresponding pixel groups may be arranged in the plurality of regions, respectively. A floating diffusion node may be placed (or formed) in a center portion of each region. Here, the region means a region on a two-dimensional plane extending in the X-axis direction and the Y-axis direction.

For example, the first floating diffusion node FD1 may be disposed in a middle portion of a first region where the first photodiodes PD11 to PD14 are arranged, the second floating diffusion node FD2 may be disposed in a middle portion of a second region where the second photodiodes PD21 to PD24 are arranged, the third floating diffusion node FD3 may be disposed in a middle portion of a third region where the third photodiodes PD31 to PD34 are arranged, and the fourth floating diffusion node FD4 may be disposed in a middle portion of a fourth region where fourth photodiodes PD41 to PD44 are arranged.

According to an embodiment, the first region, the second region, the third region, and the fourth region may each include a plurality of photodiode regions (e.g., first to fourth photodiode regions) in which a plurality of photodiodes are arranged, and the plurality of photodiode regions may include four corner regions (e.g., an upper left corner region, an upper right corner region, a lower left corner region, and a lower right corner region). Floating diffusion nodes may be placed at different corner regions in one or more photodiode regions from among a plurality of photodiode regions. The different corner regions (or edge regions) where floating diffusion nodes are formed may be adjacent to each other.

For example, the first region in which the first photodiodes PD11 to PD14 provided in the first pixel group PG1 are arranged may include a first photodiode region in which the first photodiode PD11 is disposed, a second photodiode region in which the first photodiode PD12 is disposed, a third photodiode region in which the first photodiode PD13 is disposed, and a fourth photodiode region in which the first photodiode PD14 is disposed, and the first floating diffusion node FD1 may include a lower left corner region of the first photodiode region, a lower right corner region of the second photodiode region, and an upper right corner region of the third photodiode region. In this way, corner regions in which the first floating diffusion node FD1 is formed may have different positions within each photodiode region and may also be adjacent to one another.

The event floating diffusion node EFD may be placed in a corner region of at least one photodiode region excluding one or more photodiode regions where the floating diffusion node is placed from among pixel regions. A corner region in which the event floating diffusion node EFD is formed may not be adjacent to the one or more photodiode regions where the floating diffusion node is formed.

For example, the event floating diffusion node EFD may be placed in the lower right corner region of the fourth photodiode region of the first region. The lower right corner region of the fourth photodiode region is not adjacent to the first photodiode region, the second photodiode region, and the third photodiode region, and is also not adjacent to the corner regions where the first floating diffusion node FD1 is formed.

In this way, the corner region where the event floating diffusion node EFD is formed may not be adjacent to the corner regions where floating diffusion nodes are formed, and the event floating diffusion node EFD may be electrically isolated from the floating diffusion nodes FD1, FD2, FD3, and FD4. In other words, the event floating diffusion node EFD may not be electrically connected to floating diffusion nodes.

As shown in FIG. 4, the corner regions where the event floating diffusion node EFD is placed in the first region, the second region, and the fourth region may be adjacent to one another. However, the disclosure is not limited thereto, and, according to embodiments, corner regions where the event floating diffusion node EFD is laced may not be adjacent to one another.

Referring to FIG. 5, the pixel array 110 may include a plurality of pixel groups (e.g., the first pixel group PG1, the second pixel group PG2, the third pixel group PG3, and the fourth pixel group PG4) and the pixel circuits PC (e.g., a first pixel circuit PC1, a second pixel circuit PC2, a third pixel circuit PC3, and a fourth pixel circuit PC4) electrically connected to the plurality of pixel groups.

At least one pixel group from among the plurality of pixel groups (e.g., the first pixel group PG1, the second pixel group PG2, and the fourth pixel group PG4) may include the plurality of first pixels PX1 and the second pixel PX2. From among the plurality of pixel groups, pixel groups (e.g., the third pixel group PG3) other than at least one pixel group may include the plurality of first pixels PX1 excluding the second pixel PX2. The pixel array 110 may further include the DVS circuit (e.g., 220 of FIG. 12) electrically connected to the second pixels PX2 provided in the first pixel group PG1, the second pixel group PG2, and the fourth pixel group PG4.

The pixel circuit PC may be electrically connected to (or shared by) the first pixels PX1 included in a corresponding pixel group. The pixel circuit PC may include a reset transistor RX, a driving transistor DX (also referred to as a source follower), and a selection transistor SX. Control signals provided to pixels and the plurality of pixel circuits PC may be provided from a row driver (e.g., 120 of FIG. 2).

Each of pixels (e.g., the first pixel PX1 and the second pixel PX2) have the same structure, and each pixel may include a photodiode and a transfer transistor. A first power voltage VSS (e.g., a ground voltage) may be applied to a first terminal of a photodiode (e.g., the first photodiode PD11), and a second terminal of the photodiode may be connected to a first terminal of a transfer transistor (e.g., the transfer transistor TX11). A second terminal of the transfer transistor (e.g., the transfer transistor TX11) may be connected to a floating diffusion node (e.g., the first floating diffusion node FD1). The transfer transistor may be turned on and off in response to a transmission control signal applied to a gate terminal of the transfer transistor, and may be turned on to transmit an electrical signal generated by a photodiode (e.g., photocharges accumulated in the photodiode) to a floating diffusion node.

The pixel circuit PC may be electrically connected to (or shared by) the first pixels PX1 included in a corresponding pixel group. The pixel circuit PC may include a reset transistor RX, a driving transistor DX (also referred to as a source follower), and a selection transistor SX.

A second power voltage VDD may be applied to a first terminal of the reset transistor RX, and a second terminal of the reset transistor RX may be connected to a floating diffusion node. The reset transistor RX may be turned on and off in response to a reset control signal RST applied to a gate terminal of the reset transistor RX, and may be turned on to apply the second power voltage VDD to a floating diffusion node, thereby resetting the floating diffusion node.

The second power voltage VDD may be applied to a first terminal of a driving transistor DX, and a second terminal of the driving transistor DX may be connected to a first terminal of the selection transistor SX. The driving transistor DX may operate as a source follower and generate a pixel signal (e.g., a pixel voltage) corresponding to a potential of the floating diffusion node. The potential of the floating diffusion node may be varied according to the amount of photocharges accumulated in the floating diffusion node.

The selection transistor SX may be turned on and off in response to a selection signal SEL received at a gate terminal of the selection transistor SX, and may be turned on to connect the pixel circuit PC to a corresponding column line CL1 from among the plurality of column lines CL1. The pixel circuits PC, e.g., the first pixel circuit PC1, the second pixel circuit PC2, the third pixel circuit PC3, and the fourth pixel circuit PC4, may be connected to different first column lines CL1. According to an embodiment, some of the first pixel circuit PC1, the second pixel circuit PC2, the third pixel circuit PC3, and the fourth pixel circuit PC4 may be connected to the same first column line CL1. For example, the first pixel circuit PC1 and the third pixel circuit PC3 may be connected to the same first column line CL1, and the second pixel circuit PC2 and the fourth pixel circuit PC4 may be connected to the same first column line CL1.

In the first pixel group PG1, the plurality of transfer transistors TX11 to TX13 and the first photodiodes PD11 to PD13 provided in the first pixels PX1 may share the first floating diffusion node FD1 and the first pixel circuit PC1. In the second pixel group PG2, the plurality of transfer transistors TX21 to TX23 and the second photodiodes PD21 to PD23 provided in the first pixels PX1 may share the second floating diffusion node FD2 and the second pixel circuit PC2. In the third pixel group PG3, the plurality of transfer transistors TX31 to TX34 and the third photodiodes PD31 to PD34 provided in the first pixels PX1 may share the third floating diffusion node FD3 and the third pixel circuit PC3. In the fourth pixel group PG4, the plurality of transfer transistors TX41 to TX43 and the fourth photodiodes PD41 to PD43 provided in the first pixels PX1 may share the fourth floating diffusion node FD4 and the fourth pixel circuit PC4. In the first pixel group PG1, the second pixel group PG2, and the fourth pixel group PG4, the photodiodes PD14, PD24, PD44 connected to the transfer transistors TX14, TX24, and T44 included in the second pixels PX2 may share the event floating diffusion node EFD.

For example, in the first pixel group PG1, a first transfer transistor TX11 may be connected to the first photodiode PD11 and the first floating diffusion node FD1, a second transfer transistor TX12 may be connected to a second photodiode PD12 and the first floating diffusion node FD1, a third transfer transistor TX13 may be connected to a third photodiode PD13 and the first floating diffusion node FD1, and a fourth transfer transistor TX14 may be connected to a fourth photodiode PD14 and the event floating diffusion node EFD.

For example, in the second pixel group PG2, a first transfer transistor TX21 may be connected to a first photodiode PD21 and the second floating diffusion node FD2, a second transfer transistor TX22 may be connected to a second photodiode PD22 and the second floating diffusion node FD2, a third transfer transistor TX23 may be connected to a third photodiode PD23 and the second floating diffusion node FD2, and a fourth transfer transistor TX24 may be connected to a fourth photodiode PD24 and the event floating diffusion node EFD.

For example, in the third pixel group PG3, a first transfer transistor TX31 may be connected to a first photodiode PD31 and the third floating diffusion node FD3, a second transfer transistor TX32 may be connected to a second photodiode PD32 and the third floating diffusion node FD3, a third transfer transistor TX33 may be connected to a third photodiode PD33 and the third floating diffusion node FD3, and a fourth transfer transistor TX34 may be connected to a fourth photodiode PD34 and the third floating diffusion node FD3.

For example, a first transfer transistor TX41 of the fourth pixel group PG4 may be connected to a first photodiode PD41 and the fourth floating diffusion node FD4, a second transfer transistor TX42 may be connected to a second photodiode PD42 and the fourth floating diffusion node FD4, a third transfer transistor TX43 may be connected to a third photodiode PD43 and the fourth floating diffusion node FD4, and a fourth transfer transistor TX44 may be connected to a fourth photodiode PD44 and the event floating diffusion node EFD.

The event floating diffusion node EFD may be electrically connected to the DVS circuit (e.g., 220 of FIG. 12) through vias and metal wires. The transfer transistors TX14, TX24, and T44 may be provided with the same transmission control signal (e.g., a DVS transmission control signal TG_DVS). According to an embodiment, gate terminals of the transfer transistors TX14, TX24, and T44 may receive the DVS transmission control signal TG_DVS through the same row line.

In the image sensor 100 according to an embodiment, the event floating diffusion node EFD may be arranged to not to be electrically connected to floating diffusion nodes, e.g., first to fourth floating diffusion nodes FD1 to FD4, and may be electrically isolated therefrom. When the image sensor 100, which is a hybrid sensor, operates, signal timings of the first to fourth floating diffusion nodes FD1 to FD4 and the event floating diffusion node EFD may be separated, thereby suppressing interference and improving performance of the image sensor 100.

FIG. 6 is a cross-sectional view of a pixel array according to an embodiment.

Vertical cross-sections of the first pixel group PG1 and the second pixel group PG2 are schematically shown along a line A-A’ of FIG. 4.

A substrate SUB (e.g., a semiconductor substrate) on which the first pixel PX1 and the second pixel PX2 are formed may be provided. The third photodiode PD13, the fourth photodiode PD14 of the first pixel group PG1, the third photodiode PD23, and the fourth photodiode PD24 of the second pixel group may be arranged within the substrate SUB. The plurality of photodiodes PD13, PD14, PD23, and PD24 may be formed in regions that are physically separated from each other by a device isolation layer DTI. The device isolation layer DTI may be formed in various ways, such as front deep trench isolation (FDTI), backside deep trench isolation (BDTI), and hybrid deep trench isolation (HDTI). In a plan view, device isolation layers DTI may be arranged side-by-side in a first direction (e.g., the X-axis direction). The event floating diffusion node EFD may also be formed on the substrate SUB. The event floating diffusion nodes EFD may be formed in photodiode regions PXA14 and PXA24 that are included in different pixel groups from among photodiode regions PXA13, PXA14, PXA24, and PXA23. FIG. 6 shows that the event floating diffusion nodes EFD are formed in the photodiode regions PXA14 and PXA24. However, the disclosure is not limited thereto. The photodiode regions PXA14 and PXA24 may be completely separated from each other by the device isolation layer DTI, the event floating diffusion node EFD may be formed in each of the photodiode regions PXA14 and PXA24, and the event floating diffusion nodes EFD may be electrically connected to each other through vias and wires formed in a wiring layer WL.

The wiring layer WL may be disposed on a first surface S1 of the substrate SUB. Transistors, vias, and wires may be formed in the wiring layer WL. Transfer transistors corresponding to the plurality of photodiodes PD13, PD14, PD23, and PD24 may be formed on the wiring layer WL. For example, as shown in FIG. 6, fourth transfer transistors TX14 and TX24 may be formed on the wiring layer WL disposed on the first surface S1 of the substrate SUB.

An insulation layer IL, a color filter (e.g., a first color filter CF1 and a second color filter CF2), and micro lenses (e.g., first to fourth micro lenses ML1, ML2, ML3, and ML4) may be arranged on a second surface S2 of the substrate SUB.

The first pixel group PG1 may include first photodiodes PD13 and PD14, the first color filter CF1, the first micro-lens ML1, and the second micro-lens ML2. The second pixel group PG2 may include second photodiodes PD23 and PD24, the second color filter CF2, the third micro-lens ML3, and the fourth micro-lens ML4. However, the disclosure is not limited thereto, and nano-prisms, meta-lenses, etc. may be included instead of micro-lenses.

The insulation layer IL may be placed between the substrate SUB and the color filters (e.g., the first color filter CF1 and the second color filter CF2). For example, the insulation layer IL may have an anti-reflection function. For example, the insulation layer IL may include at least one of a silicon oxide film, a silicon nitride film, a silicon oxynitride film, and a hafnium oxide film.

The first color filter CF1 may be disposed between the first photodiode PD13 and the first micro-lens ML1, and may be disposed between the second photodiode PD14 and the second micro-lens ML2. The second color filter CF2 may be disposed between the third photodiode PD23 and the fourth micro-lens ML4, and may be disposed between the fourth photodiode PD24 and the third micro-lens ML3.

The first color filter CF1 may transmit an optical signal of a first color (e.g., an optical signal corresponding to a first wavelength band corresponding to the first color) from among optical signals received through micro-lenses (e.g., the first micro-lens ML1 and the second micro-lens ML2). Therefore, the first pixel PX1 and the second pixel PX2 of the first pixel group PG1 may receive optical signals of the first color. The second color filter CF2 may transmit an optical signal of a second color (e.g., an optical signal corresponding to a second wavelength band corresponding to the second color) from among optical signals received through micro-lenses (e.g., the third micro-lens ML3 and the fourth micro-lens ML4). Therefore, the first pixel PX1 and the second pixel PX2 of the second pixel group PG2 may receive optical signals of the second color.

For example, the first color filter CF1 may be a red color filter and the second color filter CF2 may be a green color, but the disclosure is not limited thereto.

According to an embodiment, in the hybrid image sensor 100 including the first pixel PX1 that is a CIS pixel and the second pixel PX2 that is a DVS pixel, a plurality of floating diffusion nodes (e.g., the first to fourth floating diffusion nodes FD1 to FD4) and the event floating diffusion node EFD may be separated from one another and not electrically connected. When the image sensor 100, which is a hybrid sensor, operates, the timings of the first to fourth floating diffusion nodes FD1 to FD4 and the event floating diffusion node EFD may be separated and signals thereof may be separated, thereby suppressing interference and improving the performance of the image sensor 100.

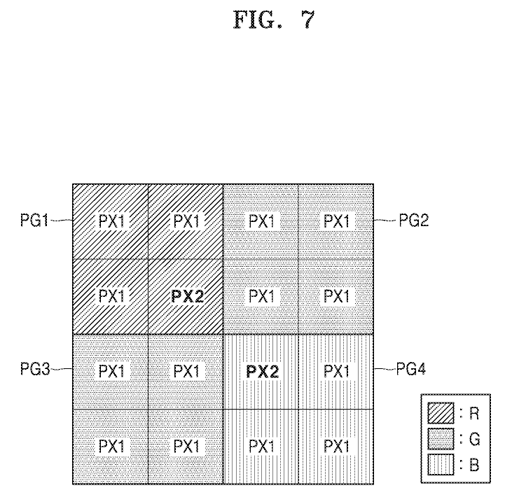

FIG. 7 is a block diagram of pixel groups PG1 to PG4 including the first pixels PX1 and the second pixels PX2, according to an embodiment. Descriptions identical to those given above with reference to FIG. 3 will be omitted.

Referring to FIG. 7, from among the first to fourth pixel groups PG1 to PG4, two pixel groups may include the plurality of first pixels PX1 and at least one second pixel PX2, and the other two pixel groups may include the plurality of first pixels PX1 excluding the second pixel PX2. For example, the first pixel group PG1 and the fourth pixel group PG4 may each include the plurality of first pixels PX1 and at least one second pixel PX2, and the second pixel group PG2 and the third pixel group PG3 may each include the plurality of first pixels PX1. The first pixel group PG1 and the fourth pixel group PG4 may be arranged in a first diagonal direction, and the second pixel group PG2 and the third pixel group PG3 may be arranged in a second diagonal direction different from the first diagonal direction. For example, in each of the first pixel group PG1 and the fourth pixel group PG4, the number of first pixels PX1 may be greater than the number of second pixels PX2.

According to an embodiment, each of the first pixel group PG1 and the fourth pixel group PG4 may include N first pixels PX1 and M second pixels PX2. For example, N may be ‘3’ and M may be ‘1’. Each of the second pixel group PG2 and the third pixel group PG3 may include four first pixels PX1.

According to an embodiment, the second pixels PX2 may be positioned at edge regions (or corner regions) where the first to fourth pixel groups PG1 to PG4 meet one another. The second pixels PX2 may each be positioned in a center portion of the first to fourth pixel groups PG1 to PG4. The second pixels PX2 may be adjacent to one another.

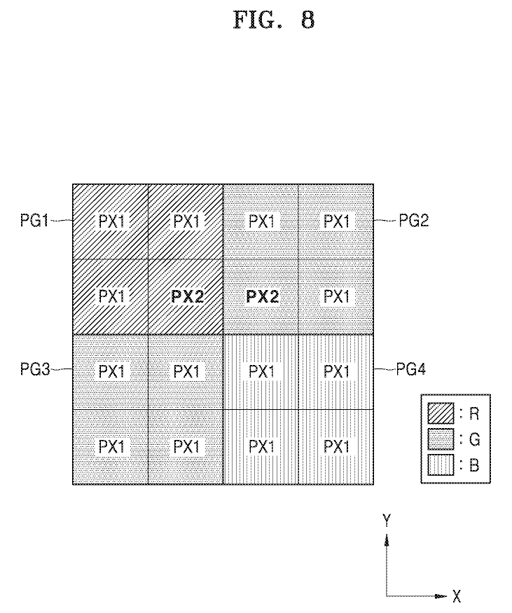

FIG. 8 is a block diagram of pixel groups PG1 to PG4including the first pixels PX1 and the second pixels PX2, according to an embodiment. Descriptions identical to those given above with reference to FIG. 3 will be omitted.

Referring to FIG. 8, from among the first to fourth pixel groups PG1 to PG4, two pixel groups may include the plurality of first pixels PX1 and at least one second pixel PX2, and the other two pixel groups may include the plurality of first pixels PX1 excluding the second pixel PX2. For example, the first pixel group PG1 and the second pixel group PG2 adjacent to each other in the first direction (e.g., the X-axis direction) may each include the plurality of first pixels PX1 and at least one second pixel PX2, and the third pixel group PG3 and the fourth pixel group PG4 adjacent to each other in the first direction may include the plurality of first pixels PX1. For example, in each of the first pixel group PG1 and the second pixel group PG2, the number of first pixels PX1 may be greater than the number of second pixels PX2.

According to an embodiment, the first pixel group PG1 and the second pixel group PG2 may each include N first pixels PX1 and M second pixels PX2. For example, N may be ‘3’ and M may be ‘1’. Each of the third pixel group PG3 and the fourth pixel group PG4 may include four first pixels PX1.

According to an embodiment, the second pixels PX2 may be positioned at edge regions where the first to fourth pixel groups PG1 to PG4 meet one another. The second pixels PX2 may each be positioned in a center portion of the first to fourth pixel groups PG1 to PG4. The second pixels PX2 may be adjacent to one another.

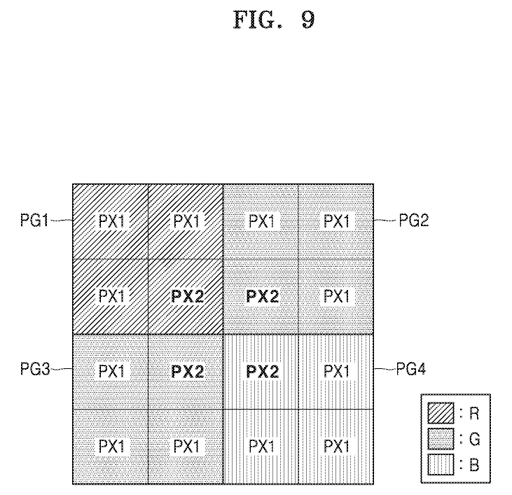

FIG. 9 is a block diagram of the first to fourth pixel groups PG1 to PG4 including the first pixels PX1 and the second pixels PX2, according to an embodiment. Descriptions identical to those given above with reference to FIG. 3 will be omitted.

Referring to FIG. 9, the first to fourth pixel groups PG1 to PG4 may each include the plurality of first pixels PX1 and at least one second pixel PX2. For example, in each of the first to fourth pixel groups PG1 to PG4, the number of first pixels PX1 may be greater than the number of second pixels PX2.

According to an embodiment, each of the first to the fourth pixel groups PG1 to PG4 may include N first pixels PX1 and M second pixels PX2. For example, N may be ‘3’ and M may be ‘1’.

According to an embodiment, the second pixels PX2 of the first to fourth pixel groups PG1 to PG4 may be positioned at edge regions where the first to fourth pixel groups PG1 to PG4 meet one another. The second pixels PX2 may each be positioned in a center portion of the first to fourth pixel groups PG1 to PG4. The second pixels PX2 may be adjacent to one another.

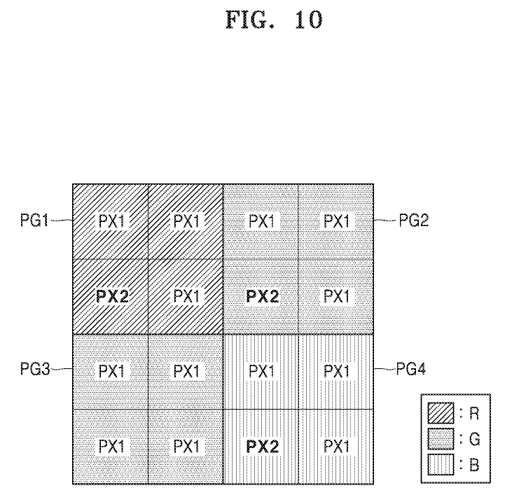

FIG. 10 is a block diagram of pixel groups PG1 to PG4 including the first pixels PX1 and the second pixels PX2, according to an embodiment. Descriptions identical to those given above with reference to FIG. 3 will be omitted.

Referring to FIG. 10, at least one pixel group from among the first to fourth pixel groups PG1 to PG4 may include the plurality of first pixels PX1 and at least one second pixel PX2. For example, the first pixel group PG1, the second pixel group PG2, and the fourth pixel group PG4 may each include the plurality of first pixels PX1 and at least one second pixel PX2. The third pixel group PG3 may include the plurality of first pixels PX1 excluding the second pixel PX2. For example, in each of the first pixel group PG1, the second pixel group PG2, and the fourth pixel group PG4, the number of the first pixels PX1 may be greater than the number of the second pixels PX2.

According to an embodiment, the first pixel group PG1, the second pixel group PG2, and the fourth pixel group PG4 may each include N first pixels PX1 and M second pixels PX2. For example, N may be ‘3’ and M may be ‘2’. The third pixel group PG3 may include four first pixels PX1.

Positions of the second pixels PX2 included in the first pixel group PG1, the second pixel group PG2, and the fourth pixel group PG4 may be the same within each pixel group. For example, the second pixels PX2 may be positioned at the lower left corner within regions where the first pixel group PG1, the second pixel group PG2, and the third pixel group PG3 are formed. For example, the second pixels PX2 may be placed to not to be adjacent to one another.

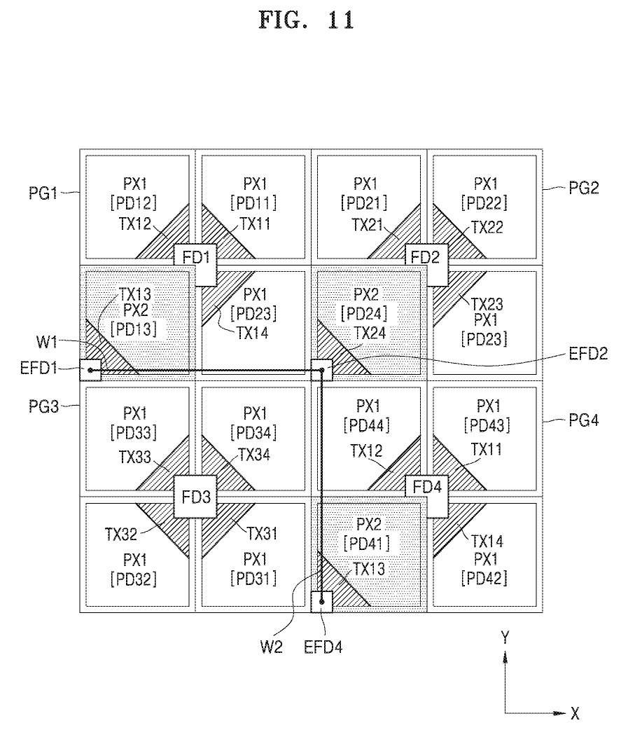

FIG. 11 is a plan view of the pixel groups PG1 to PG4 including the first pixels PX1 and the second pixels PX2, according to an embodiment. Descriptions identical to those given above with reference to FIG. 4 will be omitted.

Referring to FIGS. 10 and 11 together, the first pixel group PG1, the second pixel group PG2, and the fourth pixel group PG4 may each include three first pixels PX1 and one second pixel PX2. The first pixel PX1 and the second pixel PX2 may each include a photodiode and a transfer transistor connected thereto.

Three first pixels PX1 included in the first pixel group PG1 may share the first floating diffusion node FD1, three first pixels PX1 included in the second pixel group PG2 may share the second floating diffusion node FD2, four first pixels PX1 included in the third pixel group PG3 may share the third floating diffusion node FD3, three first pixels PX1 included in the fourth pixel group PG4 may share the fourth floating diffusion node FD4, and the second pixel PX2 included in the first pixel group PG1, the second pixel PX2 included in the second pixel group PG2, and the second pixel PX2 included in the fourth pixel group PG4 may share an event floating diffusion node.

In each pixel group, the plurality of first pixels PX1 or the plurality of first pixels PX1 and the second pixels PX2 may be arranged in rows and columns. Floating diffusion nodes may be placed in a center portion of each pixel group, and event floating diffusion nodes (e.g., EFD1, EFD2, and EFD4) provided for respective pixel groups may be placed at the corner regions of corresponding pixel groups.

As described above with reference to FIG. 10, the second pixels PX2 included in the second pixel group PG2 and the fourth pixel group PG4 may be arranged at the same positions within the first pixel group PG1, the second pixel group PG2, and the fourth pixel group PG4. The second pixels PX2 may be placed to not to be adjacent to one another. Therefore, the event floating diffusion nodes EFD1, EFD2, and EFD4 may not be adjacent to one another.

According to an embodiment, photodiode regions in which photodiodes included in the second pixel PX2 in each pixel group are arranged (e.g., the third photodiode region in which the third photodiode PD13 of the first pixel group PG1 is disposed, the fourth photodiode region in which the second photodiode PD24 of the second pixel group PG2 is disposed, and the first photodiode region in which the fourth photodiode PD41 of the fourth pixel group PG4 is disposed) may each include four corner regions (e.g., an upper left corner region, an upper right corner region, a lower left corner region, and a lower right corner region), and the event floating diffusion nodes EFD1, EFD2, and EFD4 may be arranged in the same corner region in each photodiode region. For example, the event floating diffusion nodes EFD1, EFD2, and EFD4 may be placed in the lower left corner region of each photodiode region.

The event floating diffusion nodes EFD1, EFD2, and EFD4 may be electrically connected to one another via vias and wires (e.g., a first connection wire W1 and a second connection wire W2. Therefore, the event floating diffusion nodes EFD1, EFD2, and EFD4 may operate as one event floating node, and thus the second pixel PX2 included in the first pixel group PG1, the second pixel PX2 included in the second pixel group PG2, and the second pixel PX2 included in the fourth pixel group PG4 may share the event floating diffusion node (e.g., event floating diffusion nodes EFD1, EFD2, and EFD4).

FIG. 12 is a circuit diagram showing the DVS circuit 220 according to an embodiment.

Referring to FIG. 12, the image sensor 100 may include the DVS circuit 220 connected to the second pixels PX2. The DVS circuit 220 may include a current/voltage (I/V) converter 221, an amplifier circuit 222, and a comparator circuit 223 for detecting changes in the amount of light incident on photodiodes of the second pixels PX2. The DVS circuit 220 may be connected to the event floating diffusion node EFD shared by the plurality of second pixels PX2.

The I/V converter 221 may include a logarithmic amplifier LA and a feedback transistor FB. The logarithmic amplifier LA may convert a photocurrent IP generated by at least one photodiode into a voltage and amplify the voltage. The logarithmic amplifier LA may output a logarithmic voltage VLOG in a logarithmic scale. The I/V converter 221 may be connected to the event floating diffusion node EFD. The feedback transistor FB and the logarithmic amplifier LA may be connected to the event floating diffusion node EFD.

The amplifier circuit 222 may be configured to amplify the logarithmic voltage VLOG to generate an output voltage VDIFF. For example, the amplifier circuit 222 may include capacitors C1 and C2, a differential amplifier DA, and a switch SW operated by a reset signal RST. For example, the capacitors C1 and C2 may store electrical energy generated by at least one photodiode. For example, electrostatic capacitances of the capacitors C1 and C2 may be appropriately selected by considering a shortest time (i.e., a refractory period) between two events that may occur consecutively in one pixel. When the switch SW is switched on by the reset signal RST, pixels may be initialized. The reset signal RST may be received from the row AER circuit of the event detection circuit 160.

The comparator circuit 223 may compare a level of the output voltage VDIFF of the differential amplifier DA with a reference voltage Vref to determine whether an event detected in a pixel is an on-event or an off-event. When an event in which the intensity of light increases is detected, the comparator circuit 230 may output a signal (ON) indicating an on-event, and, when an event in which the intensity of light decreases is detected, the comparator circuit 223 may output a signal (OFF) indicating an off-event.

FIG. 13 is a diagram showing a three-stack structure of the image sensor 100, according to an embodiment. The image sensor 100 of FIG. 13 may correspond to the image sensor 100 of FIG. 1.

An embodiment of the image sensor 100 according to an embodiment is described from the perspective of its physical structure. With reference to the drawings below, an embodiment is described based on layers included in the image sensor 100 in an embodiment. To facilitate explanation of the disclosure, components shown in the drawings below may be simplified and illustrated differently from actual implemented semiconductor wafers, semiconductor chips, layers, semiconductor packages, etc.

Referring to FIG. 13, the image sensor 100 may include first to third layers L1 to L3. The first to third layers L1 to L3 may each be manufactured using different semiconductor processes or from different semiconductor wafers. A first layer L1 may be electrically connected to a second layer L2 on the second layer L2. The second layer L2 may be electrically connected to a third layer L3 on the third layer L3. In other words, the second layer L2 may be located between the first layer L1 and the third layer L3.

According to an embodiment, the first layer L1 may include a pixel array region PA and a first pad PAD1. The pixel array region PA and the first pad PAD1 may be physically separated from each other or spaced apart by a certain distance. The plurality of first pixels PX1 and the second pixel PX2 may be arranged within the pixel array region PA. For example, photodiodes of the first pixels PX1 may be formed in the pixel array region PA of the first layer L1. Photodiodes of the second pixels PX2 may be formed in the pixel array region PA of the first layer L1.

According to an embodiment, the first pixel PX1 and the second pixel PX2 may be connected to a CIS circuit 210 and the DVS circuit 220 of the second layer L2.

According to an embodiment, the first layer L1 and the second layer L2 may be connected in a copper-to-copper bonding manner.

According to an embodiment, the second layer L2 may include the CIS circuit 210, the DVS circuit 220, and a second pad PAD2. For example, the CIS circuit 210 may include a reset transistor, a driving transistor, a selection transistor, etc. According to an embodiment, the CIS circuit 210 may be formed in the first layer L1.

According to an embodiment, the CIS circuit 210 and the DVS circuit 220 of the second layer L2 may receive charges from the first layer L1 and generate output signals. An output signal generated in the first layer L1 and/or the second layer L2 may be transmitted to the third layer L3 through connection structures connected to the first pad PAD1, the second pad PAD2, and/or the third pad PAD3.

According to an embodiment, the third layer L3 may include a logic circuit region DLA and a third pad PAD3. The logic circuit region DLA may be a region for forming the row driver 120, the control logic circuit 130, and the signal processing circuit 140 of FIG. 2 described above.

The third layer L3 may include remaining components of the image sensor 100 that are not formed in the first layer L1 and the second layer L2. For example, the third layer L3 may include CIS logic, DVS logic, an analog-to-digital converter (ADC), a correlated double sampler (CDS), etc. Although not shown here, the third layer L3 may further include a processor (e.g., the processor 11 of FIG. 1) or an image signal processor (ISP).

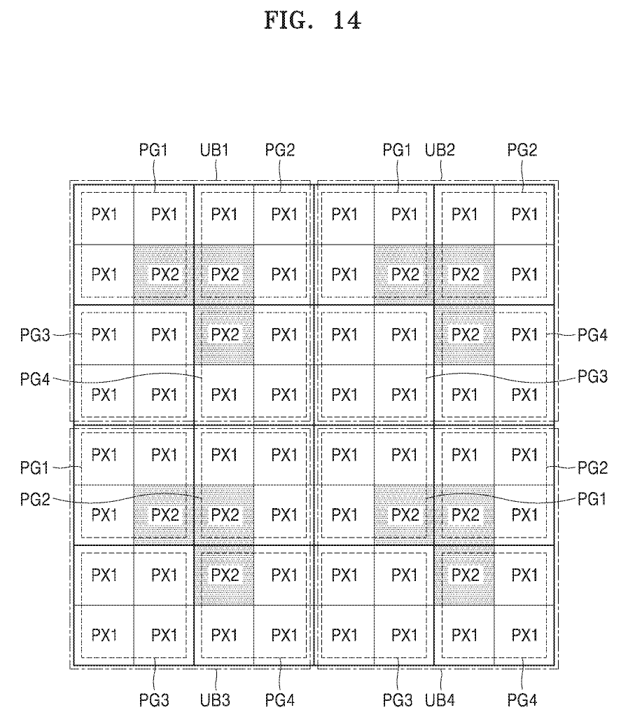

FIG. 14 is a block diagram of pixel groups PG1 to PG4 including the first pixels PX1 and the second pixels PX2, according to an embodiment. Descriptions identical to those given above with reference to FIG. 3 will be omitted.

The pixel array 110 may include a plurality of unit blocks UB1 to UB4, as shown in FIG. 14, and the plurality of unit blocks UB1 to UB4 may be arranged in rows and columns. Each of the plurality of unit blocks UB1 to UB4 may contain 16 pixel groups in a 4×4 matrix (i.e. 4 rows and 4 columns), each pixel group including first to fourth pixel groups PG1 to PG4.

One or more of the first to fourth pixel groups PG1 to PG4 may include the plurality of first pixels PX1 and at least one second pixel PX2.

An image sensor according to an embodiment may be a hybrid sensor including a CIS pixel (a first pixel) and a DVS pixel (a second pixel). Since the image sensor includes the first pixel, which is a color pixel, and the second pixel, which is a pixel of the same color as the first pixel in a pixel group, interference between pixels caused by white color pixels may be suppressed during operation of the image sensor, thereby reducing crosstalk.

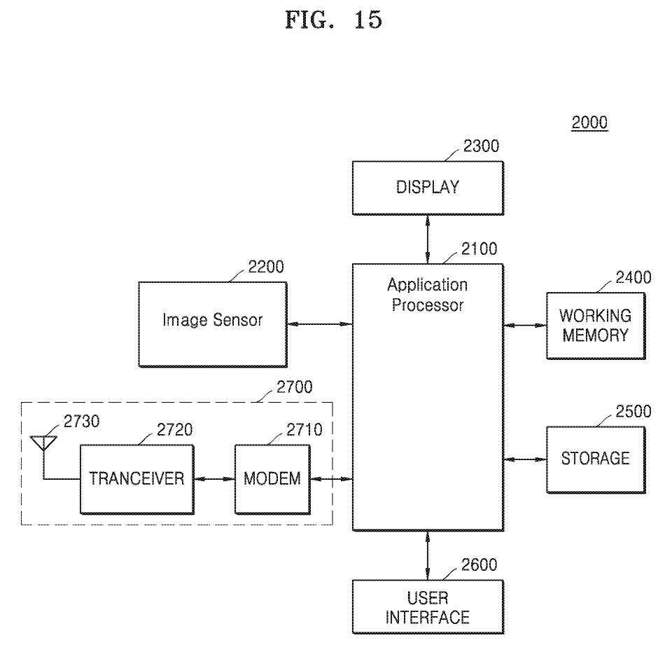

FIG. 15 is a block diagram showing an electronic device 2000 to which an image sensor according to an embodiment is applied. For example, the electronic device 2000 may be a portable terminal.

Referring to FIG. 15, the electronic device 2000 according to an embodiment may include an application processor 2100, an image sensor 2200, a display device 2300, a working memory 2400, a storage 2500, a user interface 2600, and a wireless transceiver 2700. The image sensor 100 according to embodiments described above with reference to FIGS. 1 to 14 may be applied to the image sensor 2200 shown in FIG. 15.

The application processor 2100 may control the overall operation of the electronic device 2000 and may detect movement of an object by processing event data, i.e., an event signal, received from the image sensor 2200. In other words, the application processor 2100 may perform image processing on the movement of an object based on data received from the image sensor 2200, wherein the data are related to whether an event has occurred and the amount of change in illumination for the event.

The image sensor 2200 may sense an object to generate an event signal and transmit the generated event signal to the application processor 2100. The image sensor 2200 according to an embodiment may function or operate as a standalone sensor in the electronic device 2000.

The image sensor 2200 may generate image data, such as image data, based on a received optical signal and provide the image data to the application processor 2100. Although one image sensor 2200 is shown in FIG. 15, the disclosure is not limited thereto, and the electronic device 2000 may include a plurality of image sensors 2200.

The image sensor 2200 according to an embodiment may be a hybrid sensor including a CIS pixel (a first pixel) and a DVS pixel (a second pixel). A first pixel and a second pixel (e.g., a first pixel and a second pixel included in the same pixel group) included in the image sensor 200 may be implemented as pixels of the same color, and thus interference between pixels that may occur when a first pixel and a second pixel adjacent to each other are implemented as pixels of different colors may be eliminated and crosstalk may be reduced. Therefore, the image sensor 2200 may be implemented as a hybrid sensor, and the image sensing function and the event sensing function of the image sensor 2200 may be improved, and thus the image quality of an image generated from the image sensor 2200 may be improved.

The working memory 2400 may store data used for an operation of the electronic device 2000. For example, the working memory 2400 may temporarily store packets or frames processed by the application processor 2100. The working memory 2400 may temporarily store frames containing output data received from the image sensor 2200.

The working memory 2400 may be implemented by a volatile memory such as a dynamic random access memory (DRAM) or a static RAM (SRAM) or a non-volatile resistive memory such as a ferroelectric RAM (FeRAM), a resistive RAM (RRAM), or a phase-change RAM (PRAM). The working memory 2400 may store programs and/or data processed or executed by the application processor 2100.

The storage 2500 may be implemented as a non-volatile memory device such as NAND flash or resistive memory. For example, the storage 2500 may be provided as a memory card (MMC, eMMC, SD, micro SD), etc. The storage 2500 may store data and/or programs regarding an execution algorithm that controls an image processing operation of the image sensor 2200, and, when an image processing operation is performed, the data and/or the programs may be loaded to the working memory 2400. According to an embodiment, the storage 1500 may store output image data generated by the image sensor 2200, e.g., corrected image data or post-processed image data.

The user interface 2600 may be implemented with various devices capable of receiving user inputs, e.g., a keyboard, a curtain key panel, a touch panel, a fingerprint sensor, a microphone, etc. The user interface 2600 may receive a user input and provide a signal corresponding to the received user input to the application processor 2100.

The wireless transceiver 2700 may include a tranceiver 2710, a modem 2720, and an antenna 2730.

At least one of the components, elements, modules or units (collectively “components” in this paragraph) represented by a block in the drawings, may be embodied as various numbers of hardware, software and/or firmware structures that execute respective functions described above, according to one or more example embodiments. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above example embodiments may be implemented in algorithms that execute on one or more processors. Furthermore, the components represented by a block or processing steps may employ any number of related art techniques for electronics configuration, signal processing and/or control, data processing and the like.

While the disclosure has been particularly shown and described with reference to example embodiments thereof, it will be understood that various changes in form and details may be made therein without departing from the spirit and scope of the following claims.

What is claimed is:

1. An image sensor comprising:
a pixel array comprising a plurality of pixel groups, wherein at least one pixel group from among the plurality of pixel groups comprises a first pixel configured to generate image data and a second pixel configured to generate event data, and the first pixel and the second pixel included in a same pixel group are configured to receive an optical signal of a same color; and
a dynamic vision sensor (DVS) circuit configured to generate an event signal, based on an electrical signal corresponding to a charge generated from the second pixel.

2. The image sensor of claim 1, further comprising:
a read-out circuit configured to generate image data, based on first electrical signals corresponding to charges generated from first pixels of the plurality of pixel groups; and
an event detection circuit configured to generate the event data, based on second electrical signals corresponding to charges generated from second pixels of the at least one pixel group.

3. The image sensor of claim 1, wherein the plurality of pixel groups comprise a first pixel group, a second pixel group, a third pixel group, and a fourth pixel group; the first pixel group, the second pixel group, and the fourth pixel group each comprise the first pixel and the second pixel; and the third pixel group comprises the first pixel,
wherein the first pixel and the second pixel included in the first pixel group are configured to receive an optical signal of a first color,
wherein the first pixel and the second pixel included in the second pixel group are configured to receive an optical signal of a second color,
wherein the first pixel included in the third pixel group is configured to an optical signal of a third color,
wherein the first pixel and the second pixel included in the fourth pixel group are configured to receive an optical signal of the second color, and
wherein the first color, the second color, and the third color are different from one another and are respectively one of red, green and blue.

4. The image sensor of claim 1, wherein the plurality of pixel groups are in a first layer, and
wherein the DVS circuit is connected to a pixel group from among the plurality of pixel groups and is in a second layer, the pixel group including the second pixel.

5. The image sensor of claim 1, wherein the at least one pixel group comprises a plurality of first pixels, and
wherein the plurality of first pixels share a first floating diffusion node.

6. The image sensor of claim 3, wherein a plurality of second pixels included in the first pixel group, the second pixel group, and the fourth pixel group share an event floating diffusion node.

7. The image sensor of claim 1, wherein at least two pixel groups from among the plurality of pixel groups each comprise the first pixel and the second pixel, and
wherein, in the at least two pixel groups, at least two second pixels are arranged at edge regions of the at least two pixel groups where the at least two pixel groups meet.

8. The image sensor of claim 1, wherein, in the at least one pixel group comprising the second pixel, from among the plurality of pixel groups, the second pixel is at an edge region of a corresponding pixel group of the at least one pixel group.

9. The image sensor of claim 5, wherein a plurality of first pixels included in the second pixel group share a second floating diffusion node,
wherein a plurality of first pixels included in the third pixel group share a third floating diffusion node, and
wherein a plurality of first pixels included in the fourth pixel group share a fourth floating diffusion node.

10. The image sensor of claim 1, wherein the first pixel included in the plurality of pixel groups comprises any one of a first color pixel, a second color pixel, and a third color pixel, and
wherein the second pixel included in the plurality of pixel groups includes any one of the first color pixel, the second color pixel, and the third color pixel.

11. The image sensor of claim 1, wherein the first pixel and the second pixel are produced through a same manufacturing process and comprise a same color filter.

12. An image sensor comprising:
a pixel array comprising a plurality of pixel groups, wherein at least one pixel group from among the plurality of pixel groups comprises a first pixel and a second pixel;
a dynamic vision sensor (DVS) circuit configured to generate an event signal, based on a first electrical signal corresponding to a charge generated from the second pixel;
a pixel circuit configured to generate a pixel signal, based on a second electrical signal corresponding to a charge generated from the first pixel;
a read-out circuit configured to generate image data, based on the pixel signal; and
an event detection circuit configured to generate event data based on the event signal,
wherein, from among the plurality of pixel groups, a first pixel group comprises N first pixels and M second pixels (N and M are natural numbers), and
wherein the N first pixels and the M second pixels are configured to receive optical signals of a first color and convert the optical signals into electrical signals.

13. The image sensor of claim 12, wherein the first color is one of red, green, blue, cyan, yellow, and magenta.

14. The image sensor of claim 12, wherein the DVS circuit comprises:
a current/voltage converter configured to convert a current from a second photodiode provided in the second pixel into a voltage;
an amplifier circuit configured to amplify a voltage level of the voltage to generate an output voltage; and
a comparator circuit configured to identify whether an event has occurred, based on a result of comparison between the output voltage and a reference voltage, and generate the event signal based on identifying that the event has occurred.

15. The image sensor of claim 12, wherein the plurality of pixel groups further comprise a second pixel group, a third pixel group, and a fourth pixel group,
wherein the first pixel and the second pixel of the second pixel group are configured to receive an optical signal of a second color,
wherein the first pixel of the third pixel group is configured to receive an optical signal of a third color,
wherein the first pixel and the second pixel of the fourth pixel group are configured to receive an optical signal of the second color, and
wherein the second color and the third color are at least one of red, green, blue, cyan, yellow, and magenta.

16. The image sensor of claim 15, wherein the N first pixels included in the first pixel group share a first floating diffusion node,
wherein first pixels included in the second pixel group share a second floating diffusion node,
wherein first pixels included in the third pixel group share a third floating diffusion node, and
wherein first pixels included in the fourth pixel group share a fourth floating diffusion node.

17. The image sensor of claim 16, wherein second pixels included in the first pixel group, the second pixel group, and the fourth pixel group share an event floating diffusion node, and
wherein the event floating diffusion node is not electrically connected to the first floating diffusion node, the second floating diffusion node, the third floating diffusion node, and the fourth floating diffusion node.

18. The image sensor of claim 12, wherein at least three pixel groups adjacent to one another from among the plurality of pixel groups comprise second pixels, and at least three second pixels provided in the at least three pixel groups are arranged at edge regions of the at least three pixel groups where the at least three pixel groups meet.

19. An image processing device comprising:
a pixel array comprising a plurality of pixel groups, wherein at least one pixel group from among the plurality of pixel groups comprises a first pixel and a second pixel;
a signal processing circuit configured to process a signal received from the pixel array and output data; and
a processor configured to detect a movement of an object based on the output data,
wherein the first pixel and the second pixel included in a first pixel group from among the at least one pixel group are configured to receive an optical signal of a first color, and
wherein the first color is one of red, green, and blue.

20. The image processing device of claim 19, wherein a plurality of first pixels included in the first pixel group share a first floating diffusion node, and
wherein an event floating diffusion node to which the second pixel included in the first pixel group is electrically connected is not electrically connected to the first floating diffusion node.
